(19) United States
(12) Patent Application Publication
(10) Pub. No.: US 2026/0371730 A1
(43) Pub. Date: Nov. 19, 2026

(54) Display Device And Electronic Device Comprising Same

(71) Applicant: Samsung Display Co., Ltd., Yongin-si (KR)

(72) Inventors: Jae Hwan Chu, Yongin-si (KR); Eun Hye Ko, Yongin-si (KR); Kyoung Seok Son, Yongin-si (KR); Seung Hun Lee, Yongin-si (KR)

(73) Assignee: Samsung Display Co., Ltd., Yongin-si (KR)

(21) Appl. No.: 19/468,162

(22) Filed: Feb. 3, 2026

(30) Foreign Application Priority Data
May 15, 2025 (KR) 10-2025-0063223

(51) Int. Cl. H10D 86/40; H10D 86/60; H10K 59/12; H10K 59/131

(52) U.S. Cl. CPC H10D 86/423; H10D 86/441; H10D 86/60; H10K 59/1201; H10K 59/131

(57) ABSTRACT

A display device includes a substrate, a first transistor and a third transistor positioned on the substrate, an interlayer insulating layer positioned on the first transistor and the third transistor, a wire positioned within the interlayer insulating layer, a first base layer positioned on the interlayer insulating layer, and a second transistor and a fourth transistor positioned on the first base layer. The wire is embedded within the interlayer insulating layer. Further, an upper surface of the wire and an upper surface of the interlayer insulating layer have respective surfaces that are coplanar.

### CROSS-REFERENCE TO RELATED APPLICATION

This application claims priority to and the benefit of Korean Patent Application No. 10-2025-0063223, filed May 15, 2025, the entire contents of which are hereby incorporated by reference herein.

### TECHNICAL FIELD

The present disclosure relates to a display device and an electronic device including the same.

### BACKGROUND

Display devices across a range of existing implementations include a plurality of pixels and a driving circuit (e.g., a scan driving circuit and a data driving circuit) that controls the pixels. Each of the pixels includes a light emitting element and a pixel driving circuit that controls the light emitting element. The pixel driving circuit may include a plurality of organically connected transistors.

As resolution of display devices has gradually increased, the number of signal wires and connecting electrodes connecting light emitting elements and transistors that must be arranged within a unit area has increased, and integration of driving circuits included in pixels has also increased. As a result, it has become increasingly difficult to incorporate the components necessary to meet the demands of a high-resolution display device.

### BRIEF SUMMARY

Aspects of the present disclosure provide a display device and an electronic device which reduce leakage current and are advantageous for low-frequency driving.

An aspect of the present disclosure provides a display device including a substrate, a first transistor and a third transistor positioned on the substrate, an interlayer insulating layer positioned on the first transistor and the third transistor, and a wire positioned within the interlayer insulating layer. The wire is embedded within the interlayer insulating layer. Further, the display device also includes a first base layer positioned on the interlayer insulating layer, and a second transistor and a fourth transistor positioned on the first base layer. The display device is arranged such that an upper surface of the wire and an upper surface of the interlayer insulating layer are coplanar surfaces.

In some examples, channel materials of the first transistor and the third transistor may be different and channel materials of the second transistor and the fourth transistor may be different.

In some examples, channels of the first transistor and channels of the third transistor may include amorphous silicon, single-crystal silicon, or polycrystalline silicon.

In some examples, channels of the second transistor and channels of the fourth transistor may each include an oxide semiconductor.

In some examples, the display device may include a light emitting element. The light emitting element may be connected to the first transistor.

In some examples, a drain region of the first transistor may be connected to the light emitting element.

In some examples, the wire embedded in the interlayer insulating layer may electrically connect the first transistor and the light emitting element.

In some examples, the display device may include a first capacitor and a second capacitor. The first capacitor may be positioned in a layer between the third transistor and the second transistor, and a second capacitor may be positioned on the second transistor. The first capacitor and the second capacitor may be electrically connected through a connection wire. The connection wire may be embedded within the interlayer insulating layer, and an upper surface of the connection wire may be positioned at the same level as that of an upper surface of the interlayer insulating layer. Further, the upper surface of the connection wire may be coplanar with the upper surface of the interlayer insulating layer.

In some examples, the wire embedded in the interlayer insulating layer may include portions having different widths. For instance, in an example where the wire embedded in the interlayer insulating layer is above the first transistor in a thickness direction of the display device, the wire embedded in the interlayer insulating layer may include portions having different widths depending on proximity to the first transistor in the thickness direction.

Another aspect of the present disclosure provides an electronic device including a display device, and a frame on which the display device is mounted. The display device includes a substrate, a first transistor and a third transistor positioned on the substrate, an interlayer insulating layer positioned on the first transistor and the third transistor, and a wire positioned within the interlayer insulating layer. The wire is embedded within the interlayer insulating layer. Further, the display device also includes a first base layer positioned on the interlayer insulating layer, and a second transistor and a fourth transistor positioned on the first base layer. The display device is arranged such that an upper surface of the wire and an upper surface of the interlayer insulating layer are positioned at the same level. Put another way, the respective upper surfaces may both be at a first level within the display device.

In some examples, channel materials of the first transistor and the third transistor may be the same, and channel materials of the second transistor and the fourth transistor may be the same.

In some examples, channel materials of the first transistor and the third transistor may be different and channel materials of the second transistor and the fourth transistor may be different.

In some examples, channels of the first transistor and the third transistor may include amorphous silicon, single-crystal silicon, or polycrystalline silicon.

In some examples, channels of the second transistor and the fourth transistor may each include an oxide semiconductor.

In some examples, the first transistor and the third transistor may be positioned in the same layer, and the second transistor and the fourth transistor may be positioned in the same layer. For example, the first transistor may be positioned in a first layer of the display device and the third transistor is positioned in the first layer, and the second transistor may be positioned in a second layer of the display device and the fourth transistor is positioned in the second layer. In some variations of this example, the first layer and the second layer may be the same layer. In other variations, the first layer and the second layer may be different layers.

In some examples, the electronic device may include a light emitting element connected to the first transistor. In these examples, the wire embedded in the interlayer insulating layer may electrically connect the first transistor and the light emitting element.

In some examples, the electronic device may include a first capacitor positioned in a layer between the third transistor and the second transistor, and a second capacitor positioned on the second transistor. The first capacitor and the second capacitor may be electrically connected through a connection wire.

In some examples, the connection wire may be embedded within the interlayer insulating layer, and an upper surface of the connection wire may be positioned at the same level as that of the upper surface of the interlayer insulating layer.

In some examples, the wire embedded in the interlayer insulating layer may include portions having different widths. For instance, in an example where the wire embedded in the interlayer insulating layer is above the first transistor in a thickness direction of the display device, the wire embedded in the interlayer insulating layer may include portions having different widths depending on proximity to the first transistor in the thickness direction.

According to the embodiments, a display device and an electronic device are provided that reduce leakage current and are advantageous for low-frequency driving.

### BRIEF DESCRIPTION OF THE DRAWINGS

FIG. 1 illustrates a block diagram of an electronic device according to an embodiment of the present disclosure.

FIG. 2 illustrates a schematic diagram of an electronic device according to various embodiments of the present disclosure.

FIG. 3 illustrates an exploded perspective view of an electronic device according to an embodiment of the present disclosure.

FIG. 4 illustrates a schematic cross-sectional view of a display device according to an embodiment of the present disclosure.

FIG. 5 illustrates a top plan view of a display panel according to an embodiment of the present disclosure.

FIG. 6 illustrates a circuit diagram showing a pixel according to an embodiment of the present disclosure.

FIG. 7 illustrates a schematic cross-sectional view of a pixel according to an embodiment of the present disclosure.

FIGS. 8-13 illustrate steps of a manufacturing process of an embedded wire via cross-sectional views of a portion of a pixel according to an embodiment of the present disclosure.

### DETAILED DESCRIPTION

The present disclosure will be described more fully hereinafter with reference to the accompanying drawings, in which certain embodiments of the present disclosure are shown. As those skilled in the art will appreciate, the described embodiments may be modified in various different ways, all without departing from the spirit or scope of the present disclosure.

To ensure brevity in the description of the present disclosure, parts that are irrelevant to the description are omitted, and like numerals refer to like or similar components throughout the specification.

Further, since sizes and thicknesses of constituent members shown in the accompanying drawings are given arbitrarily and are shown in a manner to facilitate understanding and ease of description, the present disclosure is not limited to the illustrated sizes and thicknesses. In the drawings, to facilitate understanding and improve readability, the thicknesses of layers, films, panels, regions, etc., may be exaggerated for clarity.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, in the specification, the word “on” or “above” means positioned on or below a portion of an element, and does not necessarily mean positioned on the upper side of the element based on a gravitational direction.

As used herein, the term “and/or” includes any and all combinations of one or more of the associated listed items. For example, in the present disclosure, “A and/or B” refers to either A, B, or both A and B. Further, the phrase “at least one of A and B” or the phrase “at least one of A or B” indicates the case where it is A, or B, or both A and B.

In addition, the terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

In addition, unless explicitly stated to the contrary, the word “comprise” and variations such as “comprises” and “comprising” should be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side, i.e., cutting in a plane that is parallel to a thickness direction of the object portion.

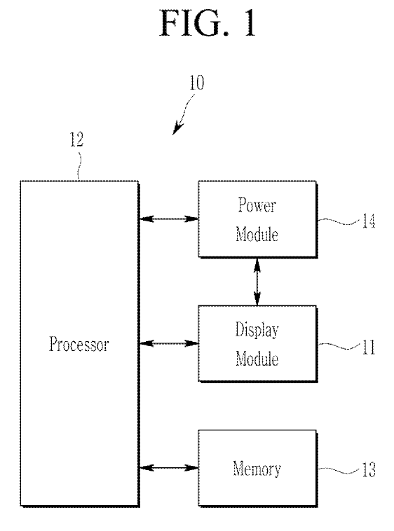

FIG. 1 illustrates a block diagram of an electronic device according to an embodiment of the present disclosure.

Referring to FIG. 1, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information necessary for operation of the processor 12 or the display module 11 may be stored in the memory 13. When the processor 12 executes an application stored in the memory 13, an image data signal and/or an input control signal may be transferred to the display module 11, and the display module 11 may process the received signal to output image information through a display screen.

The power module 14 may include a power supply module, such as a power adapter or a battery device, and a power conversion module that converts power supplied by the power supply module to generate power required for operation of the electronic device 10.

At least one of the components of the electronic device 10 described above may be included in the display device according to the embodiments described above. Additionally, some of the individual modules functionally included within a module may be included within the display device, while others may be provided separately from the display device. For example, the display device may include a display module 11, and the processor 12, the memory 13, and the power module 14 may be provided in the form of other devices within the electronic device 10 other than the display device.

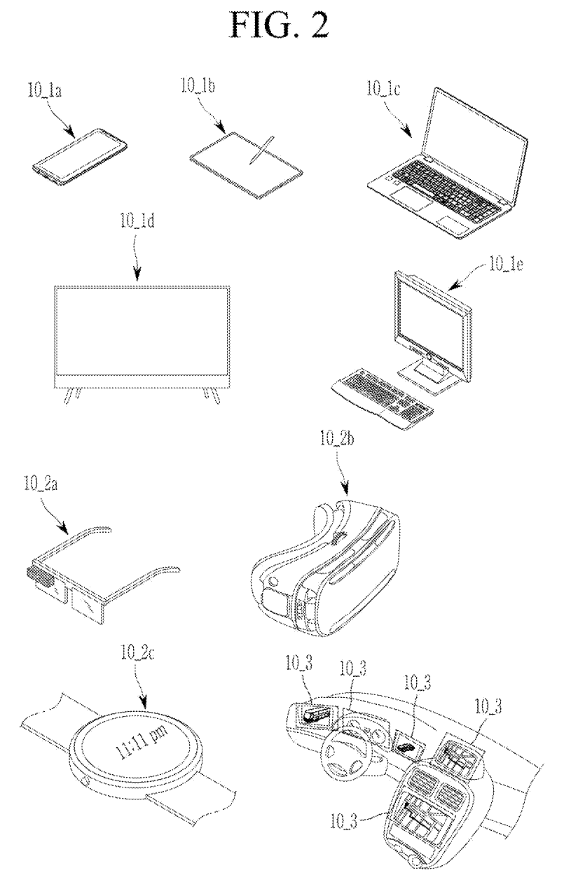

FIG. 2 illustrates a schematic diagram of an electronic device according to various embodiments of the present disclosure.

Referring to FIG. 2, various electronic devices to which display devices according to the embodiments are applied may include not only an image display electronic device such as a smart phone 10_1a, a tablet PC 10_1b, a laptop 10_1c, a TV 10_1d, or a desk monitor 10_1e, but also a wearable electronic device including a display module such as smart glasses 10_2a, a head mounted display 10_2b, or a smart watch 10_2c, and a vehicle electronic device 10_3 including a display module such as a center information display (CID) or a room mirror display arranged on a dashboard, a center fascia, a dashboard, etc. of an automobile.

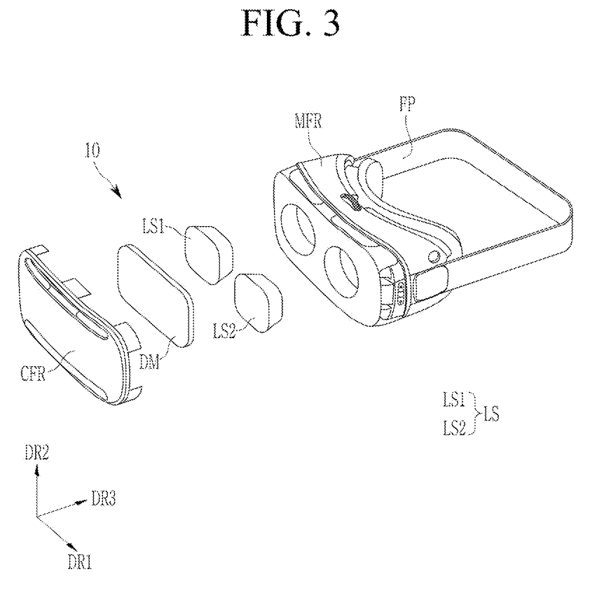

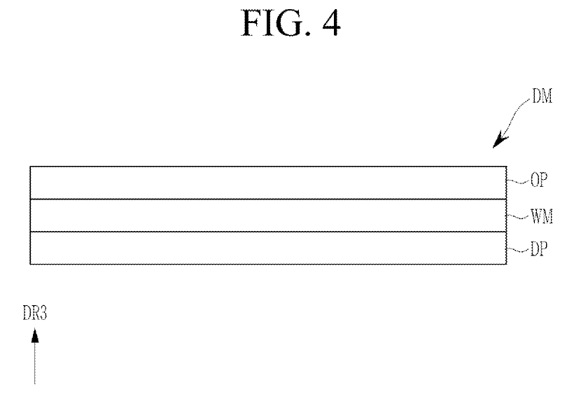

Hereinafter, an electronic device and a display device according to an embodiment of the present disclosure will be described with reference to FIGS. 3 and 4. FIG. 3 illustrates an exploded perspective view of an electronic device according to an embodiment, and FIG. 4 illustrates a schematic cross-sectional view of a display device according to an embodiment.

First, referring to FIG. 3, the electronic device 10 may be a device activated by an electrical signal. For example, the electronic device 10 may be a head mounted display (HMD). The head mounted display may be mounted on a user's head to provide a screen that displays an image or a video to the user. The head mounted display may include a see-through type of display that provides augmented reality (AR) based on actual external objects, and a see-closed type of display that provides virtual reality (VR) to the user with a screen independent of external objects.

The electronic device 10 may include a display device DM and a lens portion LS facing the display device DM. Additionally, the electronic device 10 may include a main frame MFR, a cover frame CFR, and a fixing portion FP on which the display device DM is mounted.

The main frame MFR may be a part worn on the user's face. The main frame MFR may have a shape corresponding to a shape of the user's head (face). For example, the length of the fixing portion FP may be adjusted depending on the user’s head circumference. The fixing portion FP is a structure that facilitates installation of the main frame MFR, and may include a strap, a belt, etc. However, the embodiment is not limited thereto, and the fixing portion FP may have various forms, such as a helmet or glasses temple connected to the main frame MFR.

The main frame MFR may be coupled with the cover frame CFR to provide a storage space for mounting the lens portion LS and the display device DM.

The lens portion LS may be positioned between the display device DM and the user. The lens portion LS may pass light emitted from the display device DM and provide it to the user. For example, the lens portion LS may include various types of lenses, such as a multi-channel lens, a convex lens, a concave lens, a spherical lens, an aspherical lens, a single lens, a composite lens, a standard lens, a narrow-angle lens, a wide-angle lens, a fixed-focus lens, and/or a variable-focus lens.

The lens portion LS may include a first lens LS1 and a second lens LS2. The first lens LS1 and the second lens LS2 may be positioned to correspond to positions of the user's left eye and right eye. The first lens LS1 and the second lens LS2 may be accommodated inside the main frame MFR.

The display device DM may be provided in a fixed form to the main frame MFR or may be provided in a removable form. The display device DM may provide images to the user, including both dynamic and still images. The display device DM will be described in more detail below.

The cover frame CFR may be positioned on one surface of the display device DM to protect the display device DM. The cover frame CFR and the lens portion LS may be separated from each other with the display device DM provided therebetween.

In FIG. 3, a first direction DR1, a second direction DR2, and a third direction DR3 are illustrated, and directions indicated by the first to third directions DR1, DR2, and DR3 described in this specification may be relative concepts and may be transformed into other directions. Additionally, the directions indicated by the first to third directions DR1, DR2, and DR3 may be described as the first to third directions, and may be referred to as such throughout the present disclosure. In this specification, the first direction DR1 and the second direction DR2 may be orthogonal to each other, and the third direction DR3 may be a normal direction with respect to a plane defined by the first direction DR1 and the second direction DR2.

A thickness direction of the display device DM may be parallel to the third direction DR3, which is a normal direction with respect to a plane defined by the first direction DR1 and the second direction DR2. In this specification, the front (or upper surface) and the back (or lower surface) of the members constituting the display device DM may be defined based on, e.g., relative to the third direction DR3. In this specification, “on a plane” refers to a surface parallel to the plane defined by the first direction DR1 and the second direction DR2, while “on the cross-section” refers to a surface parallel to the third direction DR3.

Referring to FIG. 4 below, the display device DM according to an embodiment may include a display panel DP, a window member WM, and an optical member OP.

The display panel DP may be configured to substantially generate an image. The image generated by the display panel DP may be viewed by the user from outside. The display panel DP may be an emissive display panel, and is not particularly limited. For example, the display panel DP may be an organic light emitting display panel or an inorganic light emitting display panel. The organic light emitting display panel may be a display panel in which a light emitting layer includes an organic light emitting material. The light emitting display panel may be a display panel in which the light emitting layer includes quantum dots, quantum rods, or micro-LEDs. Hereinafter, the display panel DP will be described as an organic light emitting display panel.

The window member WM may be positioned on the display panel DP. The window member WM may include an optically transparent insulating material. For example, the window member WM may include glass or plastic. The window member WM may have a multi-layer structure or a single-layer structure. For example, the window member WM may include a plurality of plastic films bonded together with an adhesive, or may include a glass substrate and a plastic film bonded together with an adhesive.

The optical member OP may be positioned on the display panel DP. The optical member OP may be a polarization member, a color filter, or a wavelength filter. The optical member OP may improve display characteristics of the display panel DP by controlling light incident on the optical member OP.

Although this specification describes an embodiment in which the optical member OP is positioned on the window member WM as illustrated in FIG. 4, the present disclosure is not limited thereto, and in some examples, the display panel DP, the optical member OP, and the window member WM may be positioned in that order. Alternatively, in some examples, the optical member OP may be omitted.

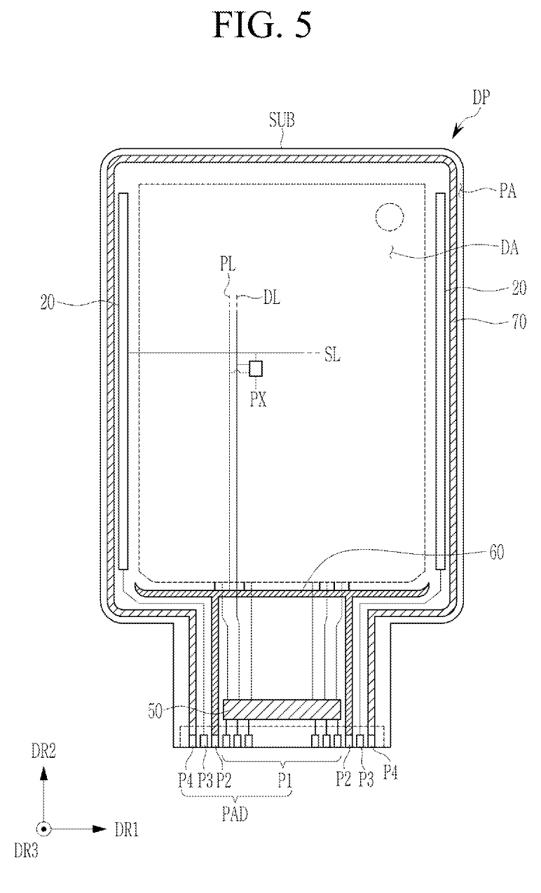

A display panel according to an embodiment will now be described with reference to FIG. 5. FIG. 5 illustrates a top plan view of a display panel according to an embodiment of the present disclosure.

Referring to FIG. 5, the display panel DP may include a plurality of pixels PX positioned in the display area DA. The pixels PX may be positioned in the display area DA. Each of the pixels PX includes a light emitting element and a pixel circuit unit connected thereto. Each of the pixels PX emits, for example, red, green, blue, or white light, and may include, for example, an organic light emitting diode.

The display panel DP may include a plurality of signal lines and a pad portion. The signal lines may include a scan line SL extending in a first direction DR1, and a data line DL and a driving voltage line PL extending in a second direction DR2.

The scan driver 20 is positioned at left and right sides of the display area DA, and generates and transfers a scan signal to each pixel PX through the scan line SL. The pixel PX may receive scan signals together from the two scan drivers 20 positioned on the left and right sides.

A pad portion PAD (referred to hereinafter as a pad portion for a circuit board) may be positioned at one end of a non-display area PA of the display panel DP, and may include a plurality of terminals P1, P2, P3, and P4. The pad portion PAD may be exposed without being covered by an insulating layer, and may be electrically connected to a flexible printed circuit board.

An IC driving chip may change multiple image signals transmitted from the outside into multiple image data signals, and may transfer the changed signals to a data driver 50 through the terminal P1. In addition, the IC driving chip may receive a vertical synchronization signal, a horizontal synchronization signal, and a clock signal to generate a control signal for controlling the driving of the scan driver 20 and the data driver 50 and transmit the control signal to each through the terminals P3 and P1. The IC driving chip may transfer a driving voltage ELVDD to a driving voltage supply wire 60 through the terminal P2. Additionally, the IC driving chip may transfer a common voltage ELVSS to each common voltage supply wire 70 through the terminal P4.

The data driver 50 may be positioned on the non-display area PA, and may generate a data voltage to be applied to each pixel PX to transfer it to each data line DL. The data driver 50 may be positioned at a side of the display panel DP—for example, between the pad portion PAD and the display area DA.

The driving voltage supply line 60 is positioned on the non-display area PA. For example, the driving voltage supply wire 60 may be positioned between the data driver 50 and the display area DA. The driving voltage supply wire 60 may provide a driving voltage to the pixels PX.

The common voltage supply wire 70 is positioned on the non-display area PA. The common voltage supply wire 70 may have a shape surrounding the substrate SUB. The common voltage supply wire 70 transfers the common voltage ELVSS to one electrode (e.g., cathode) of a light emitting element included in the pixel PX.

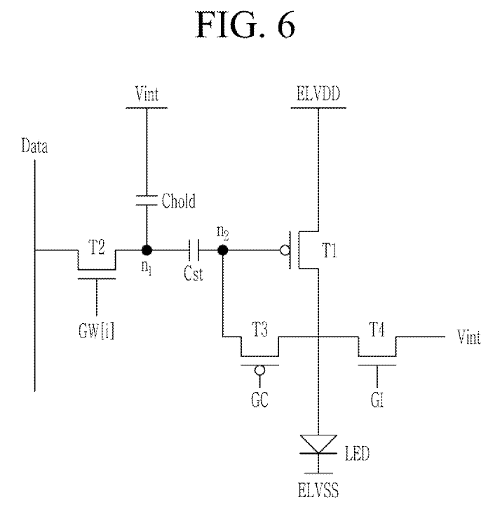

Hereinafter, a pixel will be described with reference to FIG. 6. FIG. 6 illustrates a circuit diagram showing a pixel according to an embodiment of the present disclosure.

Referring to FIG. 6, the pixel PX according to an embodiment may include a first transistor T1, a second transistor T2, a third transistor T3, a fourth transistor T4, a first capacitor Cst, and a second capacitor Chold. The pixel according to an embodiment may be referred to as having a 4T2C structure. However, the 4T2C structure is one example, and a circuit configuration of circuit SC of one pixel is not limited thereto and may also be provided in various ways according to other embodiments.

The first transistor T1 may serve as a driving transistor, and may include a gate electrode connected to a second node n2, a first electrode (input side electrode) connected to a driving voltage ELVDD, and a second electrode (output side electrode) that outputs current according to a voltage of the gate electrode. That is, the first transistor T1 may generate a light emitting current provided to the light emitting element based on the voltage stored in the first capacitor Cst. An output current of the driving transistor T1 may be transmitted to the light emitting diode (LED) to cause the LED to emit light. Luminance of the light emitted from the light emitting diode (LED) is determined based on a magnitude of an output current of the driving transistor T1.

The second transistor T2 may connect a first node n1 and the data line based on an i^{th} scan signal GWi. According to an embodiment, the second transistor T2 may transmit a data voltage DATA of the data line based on the i^{th} scan signal GWi. According to another embodiment, the second transistor T2 may serve as an NMOS transistor or a PMOS transistor. According to another embodiment, the second transistor T2 may include a gate terminal, which is a control terminal for receiving the i^{th} scan signal GWi, a first terminal connected to a data line DL, and a second terminal connected to the first node n1. The i^{th} scan signal GWi may be called a data write signal. The second transistor T2 may act as a scan transistor for transmitting the data voltage of the data line DL.

The first capacitor Cst may be connected between the first node n1 and the second node n2. The first capacitor Cst may include a first electrode connected to the first node n1 and a second electrode connected to the second node n2. The first capacitor Cst may receive the data voltage DATA output from the second transistor T2 to maintain it as a voltage of the gate electrode of the driving transistor T1. In the pixel of this embodiment, the data voltage DATA may not be directly transmitted to the gate electrode of the driving transistor T1, but may be transferred through the first capacitor Cst. This is a method of indirectly transferring the data voltage DATA to the gate electrode of the driving transistor T1 by taking advantage of the fact that when the voltage of the first electrode of the first capacitor Cst suddenly rises, the voltage of the second electrode, which is the other electrode, also rises. According to such a method, even when leakage occurs in the second transistor T2, the voltage of the gate electrode of the driving transistor T1 does not leak directly. In addition, in the present embodiment, the data voltage DATA is transferred directly to the gate electrode of the driving transistor T1 through the storage capacitor Cst without passing through another electrode of the driving transistor T1, and thus even when there is a difference in the driving voltage ELVDD depending on a position of the pixel, a voltage stored in the first capacitor Cst is determined without affecting the difference in the driving voltage ELVDD.

A second capacitor Chold may be connected between the first node n1 and a power line providing an initialization voltage Vint. The second capacitor Chold may be called a holding capacitor for maintaining a voltage of the first node n1. According to the hold capacitor Chold, the voltage of the first capacitor Cst may be held without being changed even when a surrounding signal changes, so that it may have a constant voltage.

The second transistor T3 may include a gate electrode connected to a second scan line to which a second scan signal GC is applied, a first electrode (input-side electrode) connected to the second electrode of the fourth transistor T4, and a second electrode (output-side electrode) connected to the second node n2. The third transistor T3 may enable a threshold voltage of the driving transistor T1 to be transferred to the first electrode of the first capacitor Cst and to be compensated by forming a compensation path for compensating the threshold voltage of the driving transistor T1. As a result, even when the threshold voltage of the driving transistor T1 included in each pixel is different, the driving transistor T1 may output a constant output current depending on the applied data voltage DATA. In addition, a second electrode of the third transistor T3 may be connected to a second electrode of the fourth transistor T4.

The fourth transistor T4 may include a gate electrode connected to a third scan line to which the third scan signal GI is applied, a first electrode receiving the first initialization voltage Vint, and a second electrode connected to a second electrode of the third transistor T3. The fourth transistor T4 may serve to initialize the first electrode of the first capacitor Cst and the gate electrode of the driving transistor T1 to the first initialization voltage Vint.

In this case, a channel of each of the transistors T1, T2, T3, and T4 may include amorphous silicon, single-crystal silicon, polycrystalline silicon, or an oxide semiconductor. Additionally, some transistors may include amorphous silicon, single-crystal silicon, or polycrystalline silicon, and some transistors may include oxide semiconductors. For example, the channels of the first transistor T1 and the third transistor T3 may include amorphous silicon, single-crystal silicon, or polycrystalline silicon, and the channels of the second transistor T2 and the fourth transistor T4 may include oxide semiconductors. In this way, when the channels of the second transistor T2 and the fourth transistor T4 include oxide semiconductors, a leakage current may be reduced. Additionally, there is an advantage in that interface defects may be reduced when the first transistor T1 and the third transistor T3 include single-crystal silicon, amorphous silicon, or polycrystalline silicon.

Transistors containing such different channel materials may be positioned on different layers in a manufacturing process.

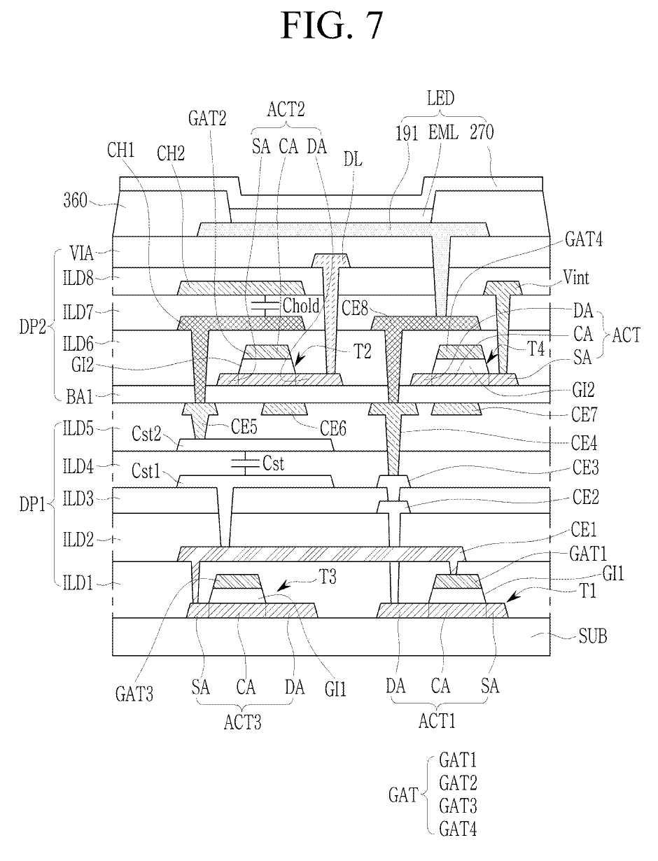

Hereinafter, a stack structure of a pixel according to an embodiment will be described with reference to FIG. 7. FIG. 7 illustrates a schematic cross-sectional view of a pixel according to an embodiment of the present disclosure.

Referring to FIG. 7, the display device according to the depicted embodiment may include a first stack DP1 and a second stack DP2. Some of the transistors may be positioned in the first stack DP1 and some of the transistors may be positioned in the second stack DP2. Specifically, the first transistor T1 and the third transistor T3 may be positioned in the first stack DP1, and the second transistor T2 and the fourth transistor T4 may be positioned in the second stack DP2. The first stack DP1 and the second stack DP2 may be formed through separate processes and then bonded. Alternatively, after forming the first stack DP1, the second stack DP2 may be formed thereon. In this case, as illustrated in FIG. 7, metal wire layers (CE4, CE5, CE6, and CE7 of FIG. 7) positioned on the upper portion of the first stack DP1 may not protrude above an uppermost insulating layer (ILD5 of FIG. 7) of the first stack DP1 but may have a structure embedded within the insulating layer. In a structure in which wire is embedded internally, a planarizing process may be omitted and the upper portion of the first stack DP1 may be planarized. Accordingly, even if the second stack DP2 is formed on the first stack DP1, an influence exerted on the upper second stack DP2 by the first stack DP1 may be reduced by the lower first stack DP1. When multiple layers are stacked, an uneven surface of a lower layer may affect formation of an upper structure. Specifically, a side angle of a formed wire may change, or the wire may not be formed flat but may be formed with uneven or bent surfaces. However, in a case of the display device and electronic device according to the presently described embodiment, a wire on the upper surface of the first stack DP1 may be embedded and planarized, so the problems associated with non-flat surfaces may be avoided or otherwise ameliorated. A specific stack structure will be described below.

Hereinafter, the first stack DP1 will first be described with reference to FIG. 7. Referring to FIG. 7, the display panel DP according to an embodiment may include a substrate SUB. The substrate SUB may include a material having a rigid characteristic such as glass, or a flexible material such as plastic or polyimide that is bendable. The substrate SUB may have a single layer or a multi-layer structure. In the substrate SUB, at least one base layer including a polymer resin sequentially stacked and at least one inorganic layer may be alternately stacked.

Although not shown, a first buffer layer may be positioned on the substrate SUB. The first buffer layer may planarize a surface of the substrate SUB, and may block penetration of impure elements. The first buffer layer may include one or more of silicon oxide (SiOₓ), silicon nitride (SiNₓ), silicon oxynitride (SiOₓN_{y}), or amorphous silicon (Si).

A first semiconductor layer ACT1 included in the first transistor T1 and a third semiconductor layer ACT3 included in the third transistor T3 may be positioned on the substrate SUB. Each of the first semiconductor layer ACT1 and the third semiconductor layer ACT3 may include amorphous silicon, single-crystal silicon, polycrystalline silicon, or an oxide semiconductor. For example, each of the first semiconductor layer ACT1 and the third semiconductor layer ACT3 may include amorphous silicon, single-crystal silicon, or polycrystalline silicon.

The first semiconductor layer ACT1 and the third semiconductor layer ACT3 may each include a channel region CA, a source region SA, and a drain region DA. A first gate insulating layer GI1 may be positioned to overlap the channel regions CA of the first semiconductor layer ACT1 and the third semiconductor layer ACT3. The first gate insulating layer GI1 may include at least one of silicon oxide (SiOₓ), silicon nitride (SiNₓ), or silicon oxynitride (SiOₓN_{y}), and may have either a single-layer or multi-layer structure including the same.

A gate electrode GAT may be positioned on the first gate insulating layer GI1. The gate electrode GAT may include a first gate electrode GAT1 of the first transistor and a third gate electrode GAT3 of the third transistor. The gate electrode GAT may include molybdenum (Mo), aluminum (Al), copper (Cu), titanium (Ti), and/or a metal oxide, and may have a single or multi-layer structure including the same. A planar shape, e.g., planar surface shape of the first gate electrode GAT1 of the first transistor T1 may be the same as that of the first gate insulating layer GI1. A planar shape, e.g., planar surface shape of the third gate electrode GAT3 of the third transistor T3 may be the same as that of the first gate insulating layer GI1. However, these shapes are merely examples, and the present disclosure is not limited thereto. The first gate electrode GAT1 and the first semiconductor layer ACT1 may form the first transistor T1, and the third gate electrode GAT3 and the third semiconductor layer ACT3 may form the third transistor T3.

Next, a first interlayer insulating layer ILD1 may be positioned on the gate electrode GAT. The first interlayer insulating layer ILD1 may include at least one of silicon oxide (SiOₓ), silicon nitride (SiNₓ), or silicon oxynitride (SiOₓN_{y}), and may have either a single-layer or multi-layer structure including the same. When the first interlayer insulating layer ILD1 is a multi-layer structure including silicon nitride and silicon oxide, the layer including the silicon nitride may be positioned closer to the substrate SUB than the layer including the silicon oxide.

A first connection electrode CE1 may be positioned on the first interlayer insulating layer ILD1. The first connection electrode CE1 may connect the first gate electrode GAT1 of the first transistor T1 and the source region SA of the third transistor T3.

Next, a second interlayer insulating layer ILD2 may be positioned on the first interlayer insulating layer ILD1. A second connection electrode CE2 may be positioned on the second interlayer insulating layer ILD2. The second connection electrode CE2 may be connected to the drain region DA of the first transistor T1 through the first interlayer insulating layer ILD1 and the second interlayer insulating layer ILD2.

Next, a third interlayer insulating layer ILD3 may be positioned on the second interlayer insulating layer ILD2. The third connection electrode CE3 and the first storage electrode Cst1 may be positioned on the third interlayer insulating layer. The third connection electrode CE3 may be connected to the second connection electrode CE2. Additionally, the first storage electrode Cst1 may be connected to the first connection electrode CE1 by extending through the second interlayer insulating layer ILD2 and the third interlayer insulating layer ILD3. The first storage electrode Cst1 may form a second electrode of the first capacitor Cst shown in FIG. 6.

Next, a fourth interlayer insulating layer ILD4 may be positioned on the third interlayer insulating layer ILD3. A second storage electrode Cst2 may be positioned on the fourth interlayer insulating layer ILD4. The second storage electrode Cst2 may be positioned to overlap the first storage electrode Cst1. The first storage electrode Cst1 and the second storage electrode Cst2 may be used to form the first capacitor Cst of FIG. 6.

A fifth interlayer insulating layer ILD5 may be positioned on the fourth interlayer insulating layer ILD4. Referring to FIG. 7, a fourth connection electrode CE4, a fifth connection electrode CE5, a sixth connection electrode CE6, and a seventh connection electrode CE7 may be positioned within the fifth interlayer insulating layer ILD5. The fourth connection electrode CE4 may be connected to the third connection electrode CE3. The fifth connection electrode CE5 may be connected to the second storage electrode Cst2. Additionally, although not shown in the cross-section of FIG. 7, the sixth connecting electrode CE6 and the seventh connecting electrode CE7 may be connected to other electrodes positioned below.

Referring to FIG. 7, upper surfaces of the fourth connection electrode CE4, the fifth connection electrode CE5, the sixth connection electrode CE6, and the seventh connection electrode CE7 may be positioned at the same level as that of the fifth interlayer insulating layer ILD5, i.e., at a first level within the display device. That is, the fourth connection electrode CE4, the fifth connection electrode CE5, the sixth connection electrode CE6, and the seventh connection electrode CE7 may not protrude over the fifth interlayer insulating layer ILD5, and may have a structure embedded within the first interlayer insulating layer ILD1. The upper surfaces of the fourth connection electrode CE4, the fifth connection electrode CE5, the sixth connection electrode CE6, and the seventh connection electrode CE7 and the upper surface of the fifth interlayer insulating layer ILD5 may be surfaces that are coplanar with each other. This will be described separately later, but the mentioned upper surfaces prepared so as to be coplanar with each other may be formed by forming the fourth connection electrode CE4, the fifth connection electrode CE5, the sixth connection electrode CE6, and the seventh connection electrode CE7 within the fifth interlayer insulating layer ILD5 through a Damascene process, and then planarizing them through a chemical mechanical polishing (CMP) process. A specific manufacturing method will be described later.

Referring to FIG. 7, a region from the substrate SUB to the fifth interlayer insulating layer ILD5 may form the first stack DP1. The second stack DP2 may be positioned on the first stack DP1. Hereinafter, a stack structure of the second stack DP2 will be described.

Referring to FIG. 7, a first base layer BA1 may be positioned on the fifth interlayer insulating layer ILD5. The first base layer BA1 may include at least one of silicon oxide (SiOₓ), silicon nitride (SiNₓ), or silicon oxynitride (SiOₓN_{y}), and may have either a single-layer or multi-layer structure including the same.

Referring to FIG. 7, a second semiconductor layer ACT2 of the second transistor T2 and a fourth semiconductor layer ACT4 of the fourth transistor T4 may be positioned on the first base layer BA1. The second semiconductor layer ACT2 and the fourth semiconductor layer ACT4 according to an embodiment may include amorphous silicon, polycrystalline silicon or an oxide semiconductor, and for example, the second semiconductor layer ACT2 and the fourth semiconductor layer ACT4 may each include an oxide semiconductor. The oxide semiconductor may include a metal oxide such as zinc (Zn), indium (In), gallium (Ga), tin (Sn), or titanium (Ti), or a mixture of metals such as zinc (Zn), indium (In), gallium (Ga), tin (Sn), or titanium (Ti) and their oxides. The oxide semiconductor may include an indium-tin oxide (ITO), an indium-gallium-zinc oxide (IGZO), a zinc oxide (ZnO), an indium-zinc oxide (IZO), a zinc-indium oxide (ZIO), an indium oxide (InO), a titanium oxide (TiO), an indium-zinc-tin oxide (IZTO), a zinc-tin oxide (ZTO), and the like. However, contemplated embodiments are not limited thereto.

The second semiconductor layer ACT2 and the fourth semiconductor layer ACT4 may each include a channel region CA, a source region SA, and a drain region DA. A second gate insulating layer GI2 may be positioned to overlap the channel regions CA of the second semiconductor layer ACT2 and the fourth semiconductor layer ACT4. The second gate insulating layer GI2 may include at least one of silicon oxide (SiOₓ), silicon nitride (SiNₓ), or silicon oxynitride (SiOₓN_{y}), and may have either a single-layer or multi-layer structure including the same.

A gate electrode GAT may be positioned on the second gate insulating layer GI2. The gate electrode GAT may include a second gate electrode GAT2 of the second transistor and a fourth gate electrode GAT4 of the fourth transistor. The gate electrode GAT may include molybdenum (Mo), aluminum (Al), copper (Cu), titanium (Ti), and/or a metal oxide, and may have a single-layer or multi-layer structure including the same. A planar shape of the second gate electrode GAT2 of the second transistor T2 may be the same as that of the second gate insulating layer GI2. A planar shape of the fourth gate electrode GAT4 of the fourth transistor T4 may be the same as that of the second gate insulating layer GI2. However, the described arrangement is an example, and the present disclosure is not limited thereto. The second gate electrode GAT2 and the second semiconductor layer ACT2 may form the second transistor T2, and the fourth gate electrode GAT4 and the fourth semiconductor layer ACT4 may form the fourth transistor T4.

Next, a sixth interlayer insulating layer ILD6 may be positioned on the gate electrode GAT. The sixth interlayer insulating layer ILD6 may include at least one of silicon oxide (SiOₓ), silicon nitride (SiNₓ), or silicon oxynitride (SiOₓN_{y}), and may have either a single-layer or multi-layer structure including the same.

A first hold electrode CH1 and an eighth connection electrode CE8 may be positioned on the sixth interlayer insulating layer ILD6. The eighth connection electrode CE8 may be connected to the fourth connection electrode CE4 by extending through the first base layer BA1 and the sixth interlayer insulating layer ILD6. As illustrated in FIG. 7, the eighth connection electrode CE8 may be connected to the drain region DA of the first transistor T1 through the fourth connection electrode CE4, the third connection electrode CE3, and the second connection electrode CE2. The first hold electrode CH1 may be connected to the fifth connection electrode CE5 by extending through the first base layer BA1 and the sixth interlayer insulating layer ILD6. As illustrated in FIG. 7, the first hold electrode CH1 may be connected to the second storage electrode Cst2 of the first capacitor Cst through the fifth connection electrode CE5.

A seventh interlayer insulating layer IL7 may be positioned on the sixth interlayer insulating layer ILD6. A second hold electrode CH2 and an initialization voltage line Vint may be positioned on the seventh interlayer insulating layer IL7. The second hold electrode CH2 may be positioned to overlap the first hold electrode CH1. The first hold electrode CH1 and the second hold electrode CH2 may form the second capacitor Chold of FIG. 6. The initialization voltage line Vint may be connected to the source region SA of the fourth transistor T4.

An eighth interlayer insulating layer IL8 may be positioned on the seventh interlayer insulating layer IL7. The data line DL may be positioned on the eighth interlayer insulating layer IL8. The data line DL may be connected to the drain region DA of the second transistor T2.

An insulating layer VIA may be positioned on the data line DL. The insulating layer VIA may include, but is not limited to, an organic material. A first electrode 191 may be positioned on the insulating layer VIA. The first electrode 191 may be connected to the eighth connection electrode CE8 by extending through the insulating layer VIA, the eighth interlayer insulating layer IL8, and the seventh interlayer insulating layer IL7. As illustrated in FIG. 7, the eighth connection electrode CE8 may be connected to the drain region DA of the first transistor T1 through the fourth connection electrode CE4, the third connection electrode CE3, and the second connection electrode CE2, so the first electrode 191 may be connected to the drain region DA of the first transistor T1 through the eighth connection electrode CE8, the fourth connection electrode CE4, the third connection electrode CE3, and the second connection electrode CE2. However, this connection method is merely an example, and the present disclosure is not limited thereto.

A partition wall 360 may be positioned on the insulating layer VIA. The partition wall 360 may include an opening that overlaps the first electrode 191. A light emitting layer EML may be positioned within the opening of the partition wall 360, and a second electrode 270 may be positioned on the partition wall 360 and the light emitting layer EML. The first electrode 191, the light emitting layer EML, and second electrode 270 may constitute a light emitting element LED. Through the described arrangement, the electrodes (i.e., wires) embedded in the insulating layers may electrically connect the first transistor T1 and the light emitting element LED.

As described above, in the display device according to the present embodiment, the first transistor T1 and the third transistor T3 may be positioned on the same layer, and the second transistor T2 and the fourth transistor T4 may be positioned on the same layer. In this case, channels of the first transistor T1 and the third transistor T3 and channels of the second transistor T2 and fourth transistor T4 may reduce interface defects while reducing a leakage current by including different materials. After forming the first transistor T1 and the third transistor T3 during the manufacturing process, the second transistor T2 and the fourth transistor T4 may be formed by stacking them thereon. In the arrangement depicted in FIG. 7, an uppermost wire of the first stack DP1 including the first transistor T1 and the third transistor T3 was embedded within an insulating layer to planarize an upper portion of the wire. Accordingly, compared to a structure in which an uppermost wire of the first stack DP1 protrudes, the second stack DP2 may be formed on a flat area, and a phenomenon of wire curling, etc. occurring due to an existing uneven surface may be minimized.

In another aspect, the present disclosure relates to a process for manufacturing a display device. A process for manufacturing a display device such as that described above and shown in FIG. 7 will be described below, with a focus on a wire embedding process.

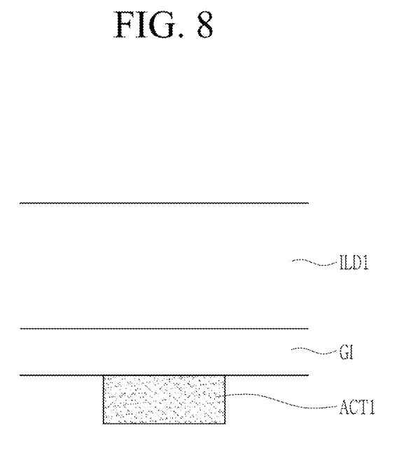

FIGS. 8-13 illustrate cross-sectional views of process steps in a manufacturing process of an embedded wire according to an embodiment of the present disclosure. For convenience of description, FIGS. 8-13 illustrate a structure in which a first semiconductor layer ACT1, a gate insulating layer GI, and a first interlayer insulating layer ILD1 are stacked. However, a method of forming an embedded wire illustrated in FIGS. 8-13 below may also be applied to the wire illustrated in FIG. 7 above.

Referring to FIG. 8, first, the first gate insulating layer GI1 and the first interlayer insulating layer ILD1 may be positioned on the first semiconductor layer ACT1. FIG. 8 illustrates a configuration in which the gate insulating layer GI covers an entire surface of the first semiconductor layer ACT1, but according to another embodiment, the gate insulating layer GI may be positioned only on a portion of the first semiconductor layer ACT1.

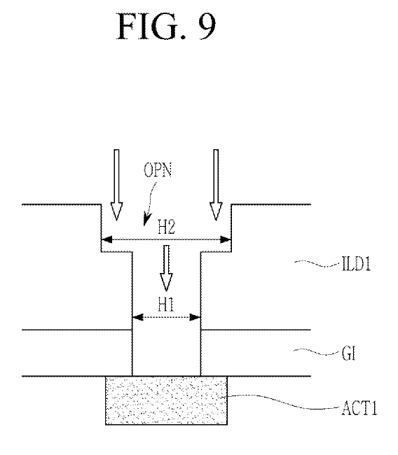

Next, referring to FIG. 9, the gate insulating layer GI and the first interlayer insulating layer ILD1 may be etched to form an opening OPN exposing the first semiconductor layer ACT1. In this case, the etching may be performed to have different widths depending on an area, i.e., proximity to the first semiconductor layer ACT1 as shown in FIG. 9, where the opening OPN is above the first semiconductor layer ACT1 in the thickness direction DR3. Later, upon completion of the manufacturing process, the first semiconductor layer ACT1 may be part of the first transistor T1. As illustrated in FIG. 9, the opening OPN formed in the first interlayer insulating layer ILD1 may have a first width H1 and a second width H2 that is greater than the first width H1. As shown in FIG. 9, a region of the opening OPN with the second width H2 may be positioned far from the first semiconductor layer ACT1.

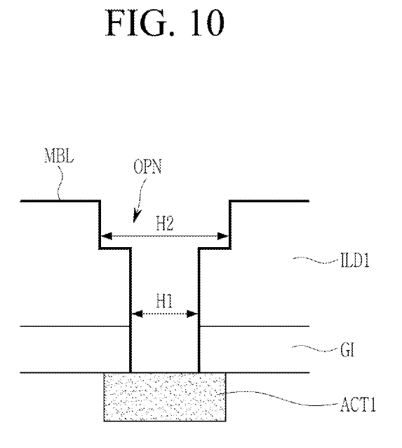

Referring to FIG. 10, a metal barrier layer MBL may be formed on upper and side surfaces of the opening OPN.

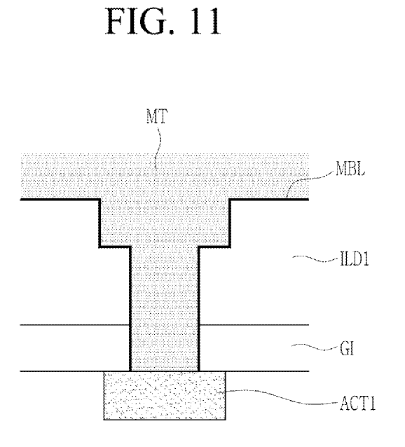

Next, referring to FIG. 11, a metal layer MT may be formed. In this case, the metal layer MT may fill an interior of the opening OPN, and may also be formed on the upper surface of the opening OPN.

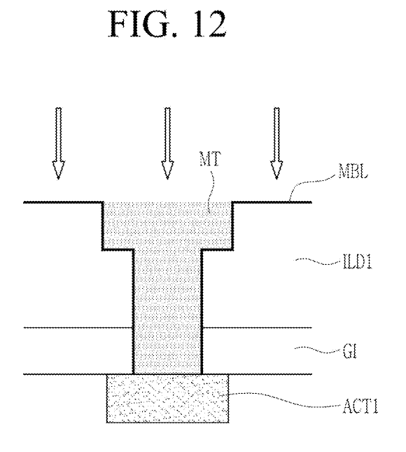

Referring to FIG. 12, an upper surface of the display device may be polished. In this process, the metal layer MT positioned outside the opening OPN may be removed.

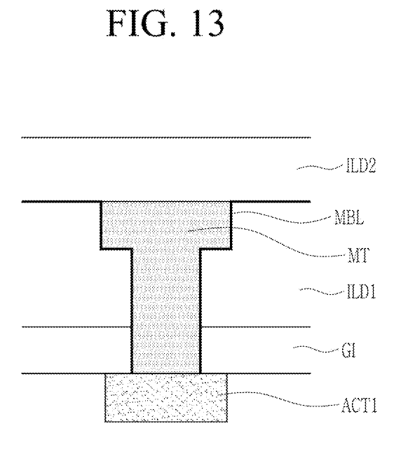

Referring to FIG. 13, a second interlayer insulating layer ILD2 may be formed. Through this process, a wire embedded within the first interlayer insulating layer ILD1 may be formed. In FIGS. 8-13, a process for embedding wire inside the first interlayer insulating layer ILD1 is described as an example, and it should be appreciated that the same process may be equally applied to embed a wire inside the seventh interlayer insulating layer ILD7.

In the display device according to the embodiment described above and shown in FIGS. 8-13, the first transistor T1 and the third transistor T3 may be positioned on the same layer, and the second transistor T2 and the fourth transistor T4 may be positioned on the same layer. In such an arrangement, an uppermost wire of the first stack DP1 including the first transistor T1 and the third transistor T3 is embedded within an insulating layer to planarize an upper portion of the wire. Accordingly, the second stack DP2 may be formed on a flat surface area, and a phenomenon of wire curling, etc. occurring due to an existing uneven surface may be minimized.

While this disclosure has been described in connection with what is presently considered to be practical embodiments, it is to be understood that the present disclosure is not limited to the disclosed embodiments, but, on the contrary, is intended to cover various modifications and equivalent arrangements included within the spirit and scope of the present disclosure.

### DESCRIPTION OF SYMBOLS

DP1: first stack
DP2: second stack
T1: first transistor
T2: second transistor
T3: third transistor
T4: fourth transistor
ACT1: first semiconductor layer
ACT2: second semiconductor layer
ACT3: third semiconductor layer
ACT4: fourth semiconductor layer

What is claimed is:

1. A display device comprising:
a substrate;
a first transistor and a third transistor positioned on the substrate;
an interlayer insulating layer positioned on the first transistor and the third transistor;
a wire positioned within the interlayer insulating layer such that the wire is embedded within the interlayer insulating layer;
a first base layer positioned on the interlayer insulating layer; and
a second transistor and a fourth transistor positioned on the first base layer,
wherein an upper surface of the wire and an upper surface of the interlayer insulating layer are coplanar surfaces.

2. The display device of claim 1, wherein
channel materials of the first transistor and the third transistor are different and
channel materials of the second transistor and the fourth transistor are different.

3. The display device of claim 1, wherein
channels of the first transistor and channels of the third transistor include amorphous silicon, single-crystal silicon, or polycrystalline silicon.

4. The display device of claim 1, wherein
channels of the second transistor and channels of the fourth transistor each include an oxide semiconductor.

5. The display device of claim 1, further comprising
a light emitting element connected to the first transistor.

6. The display device of claim 5, wherein
a drain region of the first transistor is connected to the light emitting element.

7. The display device of claim 5, wherein
the wire embedded in the interlayer insulating layer electrically connects the first transistor and the light emitting element.

8. The display device of claim 1, further comprising:
a first capacitor positioned in a layer between the third transistor and the second transistor; and
a second capacitor positioned on the second transistor,
wherein the first capacitor and the second capacitor are electrically connected through a connection wire.

9. The display device of claim 8, wherein
the connection wire is embedded within the interlayer insulating layer, and
an upper surface of the connection wire is coplanar with the upper surface of the interlayer insulating layer.

10. The display device of claim 1, wherein
the wire embedded in the interlayer insulating layer is above the first transistor in a thickness direction of the display device; and
the wire embedded in the interlayer insulating layer includes portions having different widths depending on proximity to the first transistor.

11. An electronic device comprising:
a frame; and
a display device mounted on the frame, the display device comprising:
a substrate; and
a first transistor and a third transistor positioned on the substrate;
an interlayer insulating layer positioned on the first transistor and the third transistor;
a wire positioned within the interlayer insulating layer such that the wire is embedded within the interlayer insulating layer;
a first base layer positioned on the interlayer insulating layer; and
a second transistor and a fourth transistor positioned on the first base layer,
wherein an upper surface of the wire is positioned at a first level within the display device and an upper surface of the interlayer insulating layer is positioned at the first level.

12. The electronic device of claim 11, wherein
channel materials of the first transistor and the third transistor are the same, and
channel materials of the second transistor and the fourth transistor are the same.

13. The electronic device of claim 11, wherein
channel materials of the first transistor and the third transistor are different and
channel materials of the second transistor and the fourth transistor are different.

14. The electronic device of claim 11, wherein
channels of the first transistor and channels of the third transistor include amorphous silicon, single-crystal silicon, or polycrystalline silicon.

15. The electronic device of claim 11, wherein
channels of the second transistor and channels of the fourth transistor each include an oxide semiconductor.

16. The electronic device of claim 11, wherein
the first transistor is positioned in a first layer of the display device and the third transistor is positioned in the first layer, and
the second transistor is positioned in a second layer of the display device and the fourth transistor is positioned in the second layer.

17. The electronic device of claim 11, further comprising:
a light emitting element connected to the first transistor,
wherein the wire embedded in the interlayer insulating layer electrically connects the first transistor and the light emitting element.

18. The electronic device of claim 11, further comprising:
a first capacitor positioned in a layer between the third transistor and the second transistor; and
a second capacitor positioned on the second transistor,
wherein the first capacitor and the second capacitor are electrically connected through a connection wire.

19. The electronic device of claim 18, wherein
the connection wire is embedded within the interlayer insulating layer, and
an upper surface of the connection wire is positioned at the first level.

20. The electronic device of claim 11, wherein
the wire embedded in the interlayer insulating layer is above the first transistor in a thickness direction of the display device; and
the wire embedded in the interlayer insulating layer includes portions having different widths depending on proximity to the first transistor.
